(19) United States
(12) Patent Application Publication
(10) Pub. No.: US 2007/0108540 A1
(43) Pub. Date: May 17, 2007

(54) Micro-electromechanical switch, method of manufacturing an integrated circuit including at least one such switch, and an integrated circuit

(76) Inventor: Jofre Pallares Cuxart, Barcelona (ES)

Correspondence Address: HARNESS, DICKEY & PIERCE, P.L.C., P.O. BOX 828, BLOOMFIELD HILLS, MI, 48303, US

(21) Appl. No.: 11/582,948

(22) Filed: Oct. 17, 2006

(30) Foreign Application Priority Data
Oct. 18, 2005 (EP) 05022648.9

(51) Int. Cl. H01L 29/82

(52) U.S. Cl. 257/414

(57) ABSTRACT

Integrated circuit obtained by a CMOS process and comprising circuit components and at least one micro-electromechanical switch comprising a layered structure, comprising an actuator electrode corresponding to a first conductive layer, at least one contact electrode corresponding to a second conductive layer, and a displaceable conductive element corresponding to a third conductive layer. The invention also relates to a method of manufacturing an integrated circuit including said switch, and to a circuit incorporating the switch.

### FIELD OF THE INVENTION

The invention is related to the field of switches, especially to the field of switches based on micro-electromechanical systems (MEMS), especially when implemented in integrated circuit structures, such as CMOS based structures.

### STATE OF THE ART

Micro-electromechanical systems (MEMS) are among the most promising technologies for implementing low-cost, low-power components for, for example, radio-frequency (RF) applications. The micrometric scale of MEMS devices and the possibility of integration can be useful to reduce the problems involved with the large areas occupied by passive components in conventional RF systems. The passive components can be replaced by a MEMS chip or the MEMS devices can be integrated into the processing chip of, for example, an RF system.

Nowadays, the common microwave switches currently employed in the microwave industry are mechanical switches and semiconductor switches. Mechanical coaxial and waveguide switches offer the benefits of low insertion loss, large off-state isolation, high power handling capabilities, and are highly linear. However, they are bulky, heavy and slow. On the other hand, semiconductor switches such as PIN diodes and FET based switches provide much faster switching speed, have a smaller size and less weight, but are inferior in what regards the insertion loss, DC power consumption, isolation, power handling, and linearity, than their mechanical counterparts.

MEMS switches promise to combine the advantageous properties of both mechanical and semiconductor switches. They offer the high electrical performance of the mechanical ones, while occupying the reduced area of the semiconductor implementations. These features can be helpful for improving RF systems comprising such switches, and will also allow for the implementation of new functionalities and architectures.

U.S. Pat. Nos. 5,578,976, 6,570,750, 6,657,525, 6,717,496 and 6,798,029 disclose different prior art MEMS switches.

Known prior art structures, such as those disclosed in the above-mentioned documents, may function well, but it is considered that in many cases, the design of the switches has been centered on the operation of the switch, and not on the way in which the switch can be monolithically integrated with other devices, for example, not only with other kind of MEMS structures, but also with integrated circuits (IC).

Attempts have been made to provide MEMS switches and processes for their manufacture that are compatible with standard CMOS processes (cf., for example, the abovementioned document U.S. Pat. No. 6,798,029), the well-known technology that is driving the semiconductor industry, due to its high integration and the consequent low price per unit. Known attempts appear to basically consist in fabricating the MEMS switch over a CMOS processed wafer, using several process steps that theoretically do not degrade the performance of the already built circuitry. However, apart from increasing the price of the final chip, some of these process steps can change the characteristics of the already built transistors of the wafer, for example due to the thermal features of the process.

EP-A-0709911 discloses another example of a switch in an integrated circuit.

### DESCRIPTION OF THE INVENTION

A first aspect of the invention relates to an integrated circuit comprising circuit components and including at least one micro-electromechanical switch, for example a MEMS micro-wave switch for RF applications or similar, said at least one switch comprising an actuator electrode (that is, an electrode the state of which—such as the voltage applied to it—can induce a change in the state of the switch), at least one contact electrode and a displaceable conductive element, whereby the displaceable conductive element is arranged so that it can be selectively displaced, according to the state of said actuator electrode, between an open state position—in which it is not in contact with said at least one contact electrode—and a closed state position—in which it is substantially in contact with said at least one contact electrode, and in which the switch is in a closed state—. The switch comprises a layered structure comprising at least three conductive layers at least some portions of which are separated by dielectric material, wherein:

said at least one actuator electrode is formed out of at least a part of a first one of said conductive layers;

said at least one contact electrode is formed out of a second one of said conductive layers; and

said displaceable conductive element is formed out of a third one of said conductive layers.

According to the invention, said integrated circuit, including said circuit components and said at least one switch, has been obtained by a CMOS process including deposition of subsequent conductive layers separated by dielectric material and shaped so as to define, at least, said first actuator electrode, said at least one contact electrode and said displaceable conductive element.

Thus, in accordance with the invention, a CMOS process is used not only for producing the switch but also for producing the circuit components including transistors, resistors and capacitors, that is, the CMOS process is used for producing not only the switch but the entire integrated circuit.

Obviously, electronic circuitry can be provided so as to connect the contact electrode(s) and/or the displaceable conductive element to respective input and output terminals, while control signal circuitry is provided so as to allow the relevant control signals to be applied to the actuator electrode(s) (and/or to the displaceable control element), so as to allow the switch to be operated by applying such control signals.

Thus, due to this configuration, a conventional process for manufacture of integrated circuits, such as the CMOS process, can be used for the entire fabrication of the integrated circuit including the MEMS switch or switches; only one additional etching step will be needed for releasing the movable structures, by removing parts of the dielectric material separating the relevant layers. This dielectric material acts therefore, as a sacrificial layer. Said at least one contact electrode may comprise at least two contact electrodes separated by a gap, arranged so that when said displaceable conductive element is in said closed state position, said two contact electrodes are substantially in contact with said displaceable conductive element, whereby said displaceable conductive element provides for an electrical connection between said two contact electrodes. That is, the displaceable conductive element can constitute a “bridge” between the contact electrodes. (If there is only one contact electrode, the displaceable conductive element itself can constitute an input and/or output terminal).

The displaceable conductive element can comprise a central portion supported by a plurality of support beams or similar, wherein both said central portion and said support beams are formed out of said third one of said conductive layers. This arrangement can be useful for achieving a suitable flexibility of the displaceable conductive element, allowing the relevant part of it to be displaceable enough so as to contact the contact electrode(s) when the appropriate control signal is applied to the actuator electrode(s).

The above-mentioned actuator electrode can be made of, for example, polysilicon (at least to a substantial extent). It can, for example, be embodied in a polysilicon layer proximate to a silicon substrate of an integrated circuit. It can, for example, be embodied in correspondence with a conductive layer making up parts of circuit components (such as transistor elements, resistors or capacitors) of said integrated circuit, proximate to a silicon substrate of the integrated circuit. That is, the actuator electrode can be created by steps used for the creation of other circuit elements (such as resistors, capacitors and/or transistors) of the integrated circuit.

As an alternative, the actuator electrode can be substantially of Al or of an aluminium alloy (for example, it can comprise 90% by weight or more of Al or of said aluminium alloy).

Said at least one contact electrode and/or the displaceable conductive element can be made of metal (for example, they can comprise 90% by weight or more of Al, TiN, Cu, W or any combination of thereof). In this way, these elements can be embodied by parts of the metal layers deposited during production of integrated circuits using, for example, a conventional CMOS process.

The dielectric material separating at least part of said first one and said second one of said conductive layers, and/or the dielectric material separating at least part of said second one and said third one of said conductive layers, can be SiO₂ or SiN (for example, it can comprise 90% by weight or more of SiO₂ or SiN or a mixture of both).

Said at least one contact electrode and said displaceable conductive element can be made substantially flat.

Said second one of said conductive layers, corresponding to said at least one contact electrode, can be situated between said first one of said conductive layers, corresponding to the actuator electrode, and said third one of said conductive layers, corresponding to the displaceable conductive element. Thus, the switch can be brought to its closed state by attracting the displaceable conductive element with the actuator electrode. Of course, other embodiments are possible wherein the switch can be brought into a closed state by establishing a repulsive force between the actuator electrode and the displaceable conductive element.

The switch can comprise a further actuator electrode formed out of a fourth one of the conductive layers of the switch structure, whereby said third one of said conductive layers can be situated between said fourth one of said conductive layers and said second one of said conductive layers, wherein said further actuator electrode can be arranged to contribute to the displacement of the displaceable conductive element between its closed state position and its open state position, according to the state of said further actuator electrode. Said further actuator electrode can be made of metal, for example, it can comprise at least 90% by weight of Al, TiN, Cu, W or any combination of thereof.

The circuit components of the integrated circuit can comprise, for example, transistors, resistors and/or capacitors.

A further aspect of the invention relates to an electronic circuit, for example, an electronic circuit for a radio frequency (RF) application, whereby said circuit includes the integrated circuit as described above. For example, the electronic circuit can include a plurality of filters, and the integrated circuit can include a plurality of said micro-electromechanical switches arranged as a switch matrix for selecting one of said filters to filter a signal (for example, by connecting the signal to an input of the filter). The signal can be, for example, an RF signal received by an antenna.

A further aspect of the invention relates to a method of manufacturing an integrated circuit comprising circuit components (such as transistors, resistors and/or capacitors) and a micro-electromechanical switch, said switch comprising an actuator electrode, at least one contact electrode and a displaceable conductive element, whereby the displaceable conductive element is arranged so that it can be selectively displaced, according to the state of said actuator electrode, between an open state position in which it is not in contact with said at least one contact electrode, and a closed state position in which it is substantially in contact with said at least one contact electrode and in which the switch is in a closed state.

The method comprises the steps of:

sequentially applying, on a substrate (for example, a silicon substrate), subsequent conductive layers substantially separated by dielectric material and selectively removing parts of said conductive layers so as to provide a layered structure comprising at least three conductive layers, at least some portions of which are separated by dielectric material, whereby said subsequent conductive layers are applied and/or treated so that a first one of said conductive layers establishes said at least one actuator electrode, a second one of said conductive layers establishes said at least one contact electrode, and a third one of said conductive layers establishes said displaceable conductive element; and

removing part of the dielectric material so as to make said displaceable conductive element displaceable at least with regard to said at least one contact electrode, so that said displaceable conductive element can be selectively displaced, according to the state of said actuator electrode, between an open state position in which it is not in contact with said at least one contact electrode, and a closed state position in which it is substantially in contact with said at least one contact electrode and in which the switch is in a closed state

According to the invention, the method is a CMOS process including steps for establishing said circuit components and further involving deposition of subsequent conductive layers so as to define, at least, said first actuator electrode, said at least one contact electrode and said displaceable conductive element.

What has been stated above with regard to the switch is also applicable to the method of manufacturing the circuit, mutatis mutandis.

For example, the first one of said conductive layers can be made, at least to a substantial extent, of polysilicon or aluminium.

A further aspect of the invention relates to an integrated circuit, obtained or obtainable by the method of the invention.

### BRIEF DESCRIPTION OF THE DRAWINGS

To complete the description and in order to provide for a better understanding of the invention, a set of drawings is provided. Said drawings form an integral part of the description and illustrate a possible embodiment of the invention, which should not be interpreted as restricting the scope of the invention, but just as examples of how the invention can be embodied. The drawings comprise the following figures:

FIGS. 1A-1D: schematic perspective views of different elements making up the switch, in accordance with one possible embodiment of the invention.

FIG. 2: schematic perspective view of the switch and schematic cross-section of a corresponding integrated circuit, illustrating the relation between different switch components and different layers of the circuit.

FIGS. 3 and 4: schematic partial cross sections of an integrated circuit structure during two different phases of a process of manufacturing the switch.

FIG. 5: circuit diagram schematically showing an electronic circuit for RF applications in accordance with one possible embodiment of the invention.

### DESCRIPTION OF A PREFERRED EMBODIMENT OF THE INVENTION

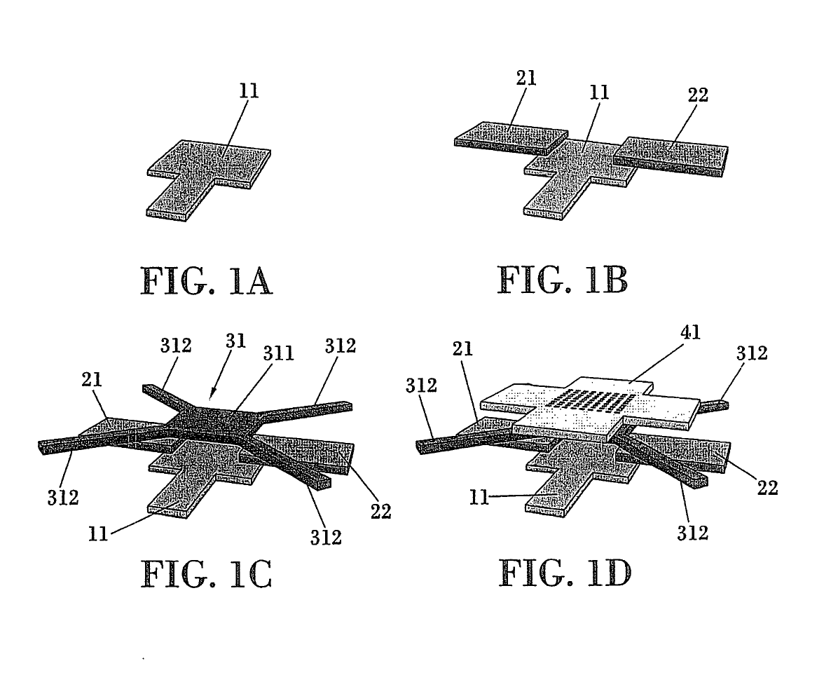

FIGS. 1A-1D schematically illustrate the composition of the switch in accordance with a possible embodiment of the invention. In a first conductive layer (such as, for example, a polysilicon layer), an actuator electrode 11 is embodied (cf. FIG. 1A). Further (FIG. 1B), in a second, subsequent, conductive (for example, metal) layer, separated from the first conductive layer by a dielectric layer, two contact electrodes (21, 22) are embodied, separated by a gap. Further (FIG. 1C) a displaceable conductive element 31 is provided, comprising a central portion 311 sustained by beams 312, all corresponding to a third conductive layer (for example, a metal layer) originally separated from the second conductive layer by a dielectric material, which is then removed to an extent so as to allow the displaceable conductive element 31 to move, so that the central portion 311 can contact the contact electrodes, thus bridging the gap between them. Thus, the two contact electrodes provide signal ports having a gap between them, so that in order that signals can flow from one port to the other, the gap must be bridged or closed, which is achieved by attracting the central portion 311 of the displaceable conductive element 31 towards the contact electrodes. This can be achieved by applying a suitable control voltage to the actuator electrode 11.

A further actuator electrode can be applied on top of the displaceable conductive element, whereby the position of this element, and thus the state of the switch (open or closed, depending on whether the displaceable conductive element is in contact with the contact electrodes or not) can be controlled by applying suitable control signals or voltages to these actuator electrodes (11, 41). The voltage difference between the respective electrode(s) and the displaceable conductive element can be used to move the central part 311 of said element towards or from the contact electrodes 21, 22.

All of the relevant layers mentioned above can be found in a typical CMOS fabrication process, where SiO₂ is often used as the insulator or dielectric that separates each layer from the next one. Thus, once the structure is fabricated following the conventional CMOS process steps, an additional process step is needed to define the switch, namely, an etching step. This step, selective between the SiO₂ and the conductive layers, will remove all of the SiO₂ (or at least the relevant parts thereof) and thus release the movable structure.

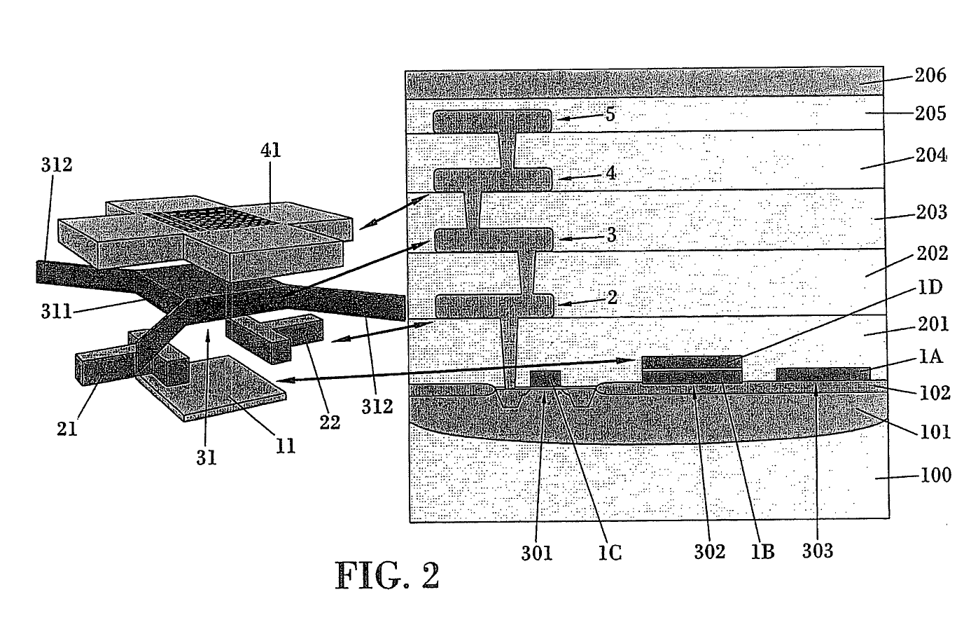

FIG. 2 illustrates a schematic view of the switch components mentioned above, and of a cross-section of an example of a conventional CMOS integrated circuit in which said components can be embodied. The circuit comprises a structure in which a p-doped silicon substrate 100 is provided, on top of which there is a further p-doped silicon layer 101 (the so-called p-well), on top of which there is a silicon dioxide layer 102. In correspondence with this silicon dioxide layer, different circuit components, such as a MOSFET transistor 301, a capacitor 302 (comprising two conductive polysilicon portions 1B and 1D) and a resistor 303, are embodied, including a conductive polysilicon portion (1C). These components are embedded in a first dielectric insulating layer 201.

Above this dielectric layer there is a plurality of metal layers (2-5) separated by the respective dielectric layers (202-205). On top of this structure, there is a protective coating 206.

The metal layers, or relevant parts thereof, can be connected by vias passing through the dielectric layers.

This layer structure can be obtained by a normal CMOS process, starting with the deposit of the silicon dioxide layer 102 on top of the substrated formed by the basic silicon substrate 100 and the p-well 101. A polysilicon layer is applied on top of the silicon dioxide layer (after performing certain conventional steps for providing, for example, transistor structures, etc.). Next, a photoresist layer is applied and then removed in certain areas, by exposition to UV-radiation, using a corresponding mask, and this step is followed by a removal step where the photoresist that has been exposed to the UV-radiation is removed. This step is in turn followed by an etching step, in which the polysilicon is removed where the photoresist has been removed, etc. This operation and other well-known steps are carried out so as to define the circuit components (such as transistors, capacitors and resistors).

Thereafter, a subsequent layer structure is obtained by applying dielectric layers followed by metal layers. Each dielectric layer (201-204) (which can be made of SiO₂ or SiN) is applied and then subjected to an photolithographic process involving application of photoresist, partial removal of the photoresist (involving exposure to UV-radiation using a mask) and etching, so as to establish vias for interconnecting subsequent metal layers. Also, the metal layers are subjected to this kind of process, which thus serves to define the shapes of the metal structures in each layer, by removing excess metal.

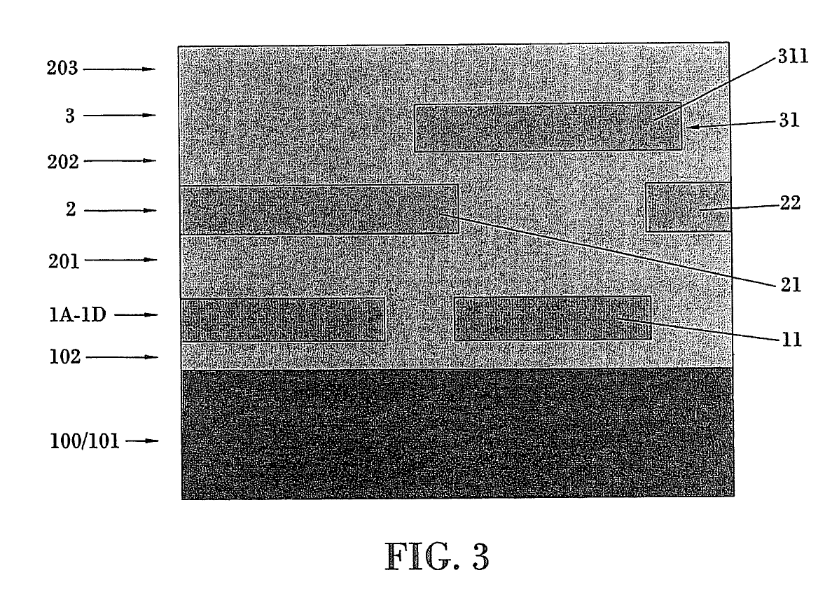

Hereby, a structure such as the one of FIG. 3 can be obtained, in which adequately shaped conductive layers or layer parts are provided, making up the actuator electrode 11, the contact electrodes 21, 22, and the displaceable conductive element 31, in correspondence with the respective conductive layers (1A-1D, 2, 3) separated by the corresponding dielectric material applied layer by layer (201-203).

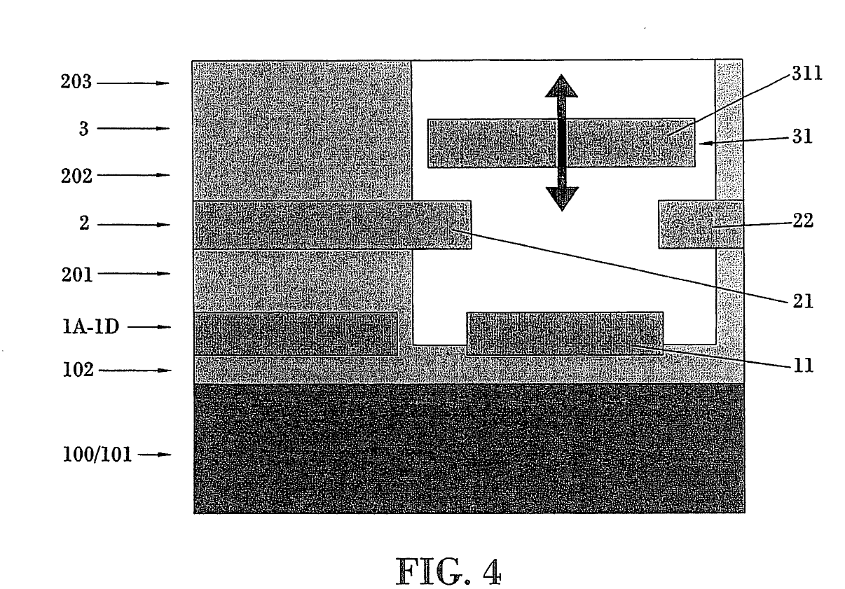

Next, part of the dielectric layers are etched away (using conventional CMOS process steps), thus removing the dielectric material (SiO₂ and/or SiN) in an area A (as shown in FIG. 4), so that the moveable conductive element 31 becomes at least partially free, with its central part 311 moveable so that it can get in contact with the contact electrodes 21, 22, when attracted towards the actuator electrode due to a corresponding voltage difference between both items.

Of course, the device can also be arranged with the displaceable conductive element 31 arranged at a level between the level of the contact electrodes 21, 22 and the level of the actuator electrode 11, whereby a repulsive force exerted on the displaceable conductive element 31 by the actuator electrode will be able to push this element 31 towards the contact electrodes 21, 22, thus closing the switch.

In FIG. 2, it is schematically illustrated how the first actuator electrode 11 can correspond to (be embodied in), for example, a polysilicon or metal layer close to the silicon substrate 100/101, for example, one of the layers (1A-1D) making up parts of the circuit elements 300-302 of the integrated circuit, whereas the contact electrodes 21, 22, the displaceable conductive element 31 and the second actuator electrode 41 can be embodied in the first 2, second 3 and third 4 metal layers of the circuit.

This invention will provide for a low cost strategy for integrating MEMS switches into standard CMOS integrated circuits, allowing the possibility of new RF system architectures without an increase of chip area or unit price. A typical RF application where new MEMS switch could be very advantageous, is a multistandard RF transceiver, working with several frequency bands and having a filter for each band, and using an RF MEMS switch in accordance with the invention to control the signal flow within this filter bank.

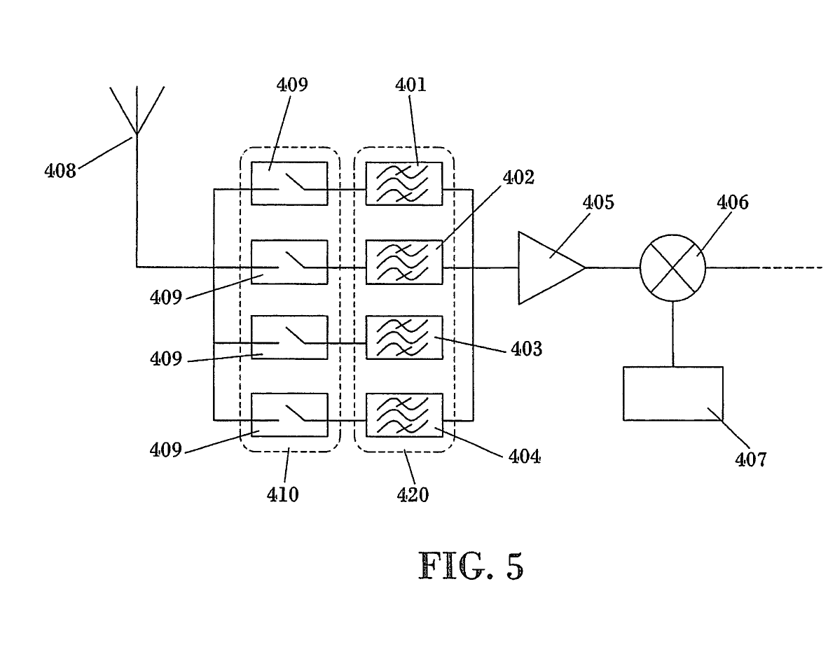

FIG. 5 illustrates an electronic RF circuit in accordance with a possible embodiment of the invention, including an antenna 408 connected to a switch matrix 410 (comprising an array of switches 409 in accordance with the invention), by means of which a signal received by the antenna can be connected or coupled to a filter selected from a plurality of filters (401-404) of a filter bank 420 forming part of the electronic circuit. In this way, an appropriate filter can be chosen for filtering the RF signal coming from the antenna 408. The circuit further comprises a low-noise amplifier (LNA) 405 arranged to receive a signal at the output end of the filter bank 420, and a mixer 406 connected to a local oscillator 407. Of course, this is only one of the infinity of electronic circuit arrangements in which the switches of the invention can be used.

Of course, the drawings only illustrate some possible examples of the circuit layout. Many other layouts are possible within the scope of the invention. For example, the described type of CMOS circuits normally contain a larger number of layers, such as seven or eight metal layers and two polysilicon layers, including sublayers having different doping.

In this text, the term “comprises” and its derivations (such as “comprising”, etc.) should not be understood in an excluding sense, that is, these terms should not be interpreted as excluding the possibility that what is described and defined may include further elements, steps, etc.

On the other hand, the invention is obviously not limited to the specific embodiment(s) described herein, but also encompasses any variations that may be considered by any person skilled in the art (for example, as regards the choice of materials, dimensions, components, configuration, etc.), within the general scope of the invention as defined in the claims.

1. An integrated circuit comprising circuit components and including at least one micro-electromechanical switch, said at least one switch comprising an actuator electrode, at least one contact electrode and a displaceable conductive element, whereby the displaceable conductive element is arranged so that it can be selectively displaced, according to the state of said actuator electrode, between an open state position in which it is not in contact with said at least one contact electrode, and a closed state position in which it is substantially in contact with said at least one contact electrode and in which the switch is in a closed state;
wherein
said switch comprises a layered structure comprising at least three conductive layers) at least some portions of which are separated by dielectric material, wherein
said at least one actuator electrode is formed out of at least a part of a first one of said conductive layers;
said at least one contact electrode is formed out of a second one of said conductive layers;
said displaceable conductive element is formed out of a third one of said conductive layers; and
said integrated circuit, including said circuit components and said at least one switch, has been obtained by a CMOS process including deposition of subsequent conductive layers separated by dielectric material and shaped so as to define, at least, said first actuator electrode, said at least one contact electrode and said displaceable conductive element.

2. An Integrated circuit according to claim 1, wherein said at least one contact electrode comprises at least two contact electrodes) separated by a gap, arranged so that when said displaceable conductive element is in said closed state position, said two contact electrodes are substantially in contact with said displaceable conductive element, whereby said displaceable conductive element provides for an electrical connection between said two contact electrodes.

3. An integrated circuit according to claim 1, wherein the displaceable conductive element (31) comprises a central portion (311) supported by a plurality of support beams (312), wherein both said central portion and said support beams are formed out of said third one (3) of said conductive layers.

4. An integrated circuit according to claim 1, wherein said actuator electrode is made of polysilicon.

5. An integrated circuit according to claim 1, wherein said actuator electrode is embodied in a polysilicon layer proximate to a silicon substrate of an integrated circuit.

6. An integrated circuit according to claim 1, wherein said actuator electrode is embodied in correspondence with a conductive layer making up parts of the circuit components of said integrated circuit, proximate to a silicon substrate of an integrated circuit.

7. An integrated circuit according to claim 1, wherein said actuator electrode is substantially of Al or of an aluminium alloy.

8. An integrated circuit according to claim 1, wherein said at least one contact electrode is made of metal.

9. An integrated circuit according to claim 1, wherein said displaceable conductive element is made of metal.

10. An integrated circuit according to claim 8, wherein said metal comprises at least 90% by weight of Al, TiN, Cu, W or any combination of thereof.

11. An integrated circuit according to claim 1, wherein said dielectric material separating at least part of said first one and said second one of said conductive layers, is SiO₂ or SiN.

12. An integrated circuit according to claim 1, wherein said dielectric material separating at least part of said second one and said third one of said conductive layers, is SiO₂ or SiN.

13. An integrated circuit according to claim 1, wherein said at least one contact electrode and said displaceable conductive element are substantially flat.

14. An integrated circuit according to claim 1, wherein said second one of said conductive layers, corresponding to said at least one contact electrode, is situated between said first one of said conductive layers, corresponding to the actuator electrode, and said third one of said conductive layers, corresponding to the displaceable conductive element.

15. An integrated circuit according to claim 1, further comprising a further actuator electrode formed out of a fourth one of the conductive layers of the switch structure, whereby said third one of said conductive layers is situated between said fourth one of said conductive layers and said second one of said conductive layers, wherein said further actuator electrode is arranged to contribute to the displacement of the displaceable conductive element between its closed state position and its open state position, according to the state of said further actuator electrode.

16. An integrated circuit according to claim 15, wherein said further actuator electrode is made of metal.

17. An integrated circuit according to claim 16, wherein said metal comprises at least 90% by weight of Al, TiN, Cu, W or any combination of thereof.

18. An integrated circuit according to claim 1 wherein said circuit components include transistors, resistors and capacitors.

19. An electronic circuit, including an integrated circuit according to claim 1.

20. An electronic circuit in accordance with claim 19, wherein said electronic circuit is a circuit for a radio frequency application.

21. The electronic circuit according to claim 19, wherein said electronic circuit includes a plurality of filters and wherein said integrated circuit includes a plurality of said micro-electromechanical switches arranged as a switch matrix for selecting one of said filters to filter a signal.

22. A method of manufacturing an integrated circuit comprising circuit components and at least one micro-electromechanical switch, said switch comprising an actuator electrode, at least one contact electrode and a displaceable conductive element, whereby the displaceable conductive element is arranged so that it can be selectively displaced, according to the state of said actuator electrode, between an open state position in which it is not in contact with said at least one contact electrode, and a closed state position in which it is substantially in contact with said at least one contact electrode and in which the switch is in a closed state;
wherein the method comprises the steps of:
sequentially applying, on a substrate, subsequent conductive layers substantially separated by dielectric material and selectively removing parts of said conductive layers so as to provide a layered structure comprising at least three conductive layers at least some portions of which are separated by dielectric material, whereby said subsequent conductive layers are applied so that a first one of said conductive layers establishes said at least one actuator electrode, a second one of said conductive layers establishes said at least one contact electrode, and a third one of said conductive layers establishes said displaceable conductive element;
removing part of the dielectric material so as to make said displaceable conductive element displaceable at least with regard to said at least one contact electrode, so that said displaceable conductive element can be selectively displaced, according to the state of said actuator electrode, between an open state position in which it is not in contact with said at least one contact electrode, and a closed state position in which it is substantially in contact with said at least one contact electrode and in which the switch is in a closed state;
wherein the method is a CMOS process including steps for establishing said circuit components and further involving deposition of subsequent conductive layers so as to define, at least, said first actuator electrode, said at least one contact electrode and said displaceable conductive element.

23. The method according to claim 22, wherein said second one of said conductive layers is applied so as to establish at least two contact electrodes, arranged so that when said displaceable conductive element is in said closed state position, said two contact electrodes are substantially in contact with said displaceable conductive element, whereby said displaceable conductive element provides for an electrical connection between said two contact electrodes.

24. The method according to claim 22, wherein the step of applying a third one of said conductive layers is carried out so as to produce a displaceable conductive element having a central portion supported by a plurality of support beams, whereby both said central portion and said support beams are formed out of said third one of said conductive layers.

25. The method according to claim 22, wherein said first one of said conductive layers is made of polysilicon.

26. The method according to claim 22, wherein said at least one contact electrode is made of metal.

27. The method according to claim 22, wherein said displaceable conductive element is made of metal.

28. The method according to claim 22, wherein said metal comprises at least 90% by weight of Al, TiN, Cu, W or any combination of thereof.

29. The method according to claim 22, performed so that said at least one contact electrode (21, 22) and said displaceable conductive element (31) are substantially flat.

30. The method according to claim 22, wherein said second one of said conductive layers is situated between said first one of said conductive layers and said third one of said conductive layers.

31. The method according to claim 22, further comprising the step of applying a fourth one of said conductive layers so as to establish a further actuator electrode, whereby said third one of said conductive layers is situated between said fourth one of said conductive layers and said second one of said conductive layers, wherein said further actuator electrode is established so as to contribute to the displacement of the displaceable conductive element between its closed state position and its open state position, according to the state of said further actuator electrode.

32. The method according to claim 22, wherein said circuit components include transistors, resistors and capacitors.

33. An integrated circuit, obtained by the method according to claim 22.
